(19) United States
(12) Patent Application Publication
(10) Pub. No.: US 2006/0140027 A1
(43) Pub. Date: Jun. 29, 2006

(54) Semiconductor memory device and method of operating the same

(75) Inventor: Kenichirou Tominaga, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 11/304,564

(22) Filed: Dec. 16, 2005

(30) Foreign Application Priority Data
Dec. 28, 2004 (JP) 2004-379608

(51) Int. Cl. G11C 29/00

(52) U.S. Cl. 365/200

(57) ABSTRACT

A semiconductor memory device has: a first memory including a data storage area and a redundant data storage area; a second memory as a nonvolatile memory storing a defect address of the first memory; a register; a sequencer; and a decoder. The sequencer reads out the defect address from the second memory and stores the read defect address in the register. When accessing a target address in the first memory, the decoder compares the target address with the defect address stored in the register, and selects any of the data storage area and the redundant data storage area of the first memory based on a result of the comparison.

### BACKGROUND OF THE INVENTION

1. Field of the Invention

The present invention relates to a semiconductor memory device. In particular, the present invention relates to a semiconductor memory device equipped with a nonvolatile memory, and a method of operating the semiconductor memory device.

2. Description of the Related Art

A redundancy technique is known in the field of a semiconductor memory device. If there is a problem with a data storage area (memory cell or sector) of a memory, an address of the defective data storage area is replaced with an address of a redundant data storage area (redundant memory cell or redundant sector) in the memory. In order to hold the address of the defective data storage area, a nonvolatile memory such as a flash memory is used which is capable of retaining the memory content even when a power supply is turned off.

FIG. 1 is a block diagram showing a configuration of a semiconductor memory device provided with such a non-volatile memory. The semiconductor memory device has a CPU (Central Processing Unit) 102, a first flash memory unit 110 and a second flash memory unit 120.

The first flash memory unit 110 includes a first flash memory 111 and a decoder 114. The first flash memory 111 has a plurality of data storage areas and at least one redundant data storage area. In FIG. 1, for example, the first flash memory 111 has data storage areas 112-1 to 112-N and redundant data storage areas 113-1 and 113-2.

The second flash memory unit 120 includes a second flash memory 121. Stored in the second flash memory 121 are programmed codes 122-1 to 122-N. The programmed codes 122-1 to 122-N include a plurality of addresses and a plurality of defect flags, respectively. Respective of the plurality of addresses correspond to addresses of the plurality of data storage areas 112-1 to 112-N in the first flash memory 111. Each of the plurality of defect flags indicates “1” or “0”. For example, when a defect flag included in a programmed code 122-J (J is an integer not less than 1 and not more than N) is “1”, an address included in the programmed code 122-J corresponds to an address of the redundant data storage area 113-1.

The CPU 102 performs command execution as one of its operations. In the command execution, the CPU 102 outputs a read command 153 including a target address to the decoder 114. When receiving the read command 153, the decoder 114 performs a replacement control as one of its operations. In the replacement control, the decoder 114 reads all of the programmed codes 122-1 to 122-N stored in the second flash memory 121 in response to the read command 153, and compares the target address included in the read command 153 with the addresses included in the programmed codes 122-1 to 122-N. Then, the decoder 114 accesses the first flash memory 111 based on a result of the above-mentioned comparison. The decoder 114 reads data 154 from the first flash memory 111 and outputs the read data 154 to the CPU 102.

Japanese Laid-Open Patent Application (JP-P2001-23391A) discloses a flash memory device as a relevant technique. Defect information regarding a data storage area is stored in a flash memory. More specifically, a redundancy select circuit stores an address of a defect cell by using a flash EEPROM cell. The flash EEPROM cell is similar to a main cell array.

### SUMMARY OF THE INVENTION

The present invention has recognized the following points. According to the conventional semiconductor memory device described above, the programmed codes 122-1 to 122-N stored in the second flash memory 121 are read every time the command execution or the replacement control is performed. As a result, the number of access times to the second flash memory 121 is increased, which can cause a “read retention error” as described below.

When a data is read out from a specified memory cell, a word line is activated (selected) and then data on a predetermined bit line is obtained. Here, with respect to memory cells other than the specified memory cell which are connected to the same activated word line, a slight electric field is applied to such memory cells in the same direction as in data programming. As a result, electrons are gradually injected into a floating gate of the memory cell other than the specified memory cell due to the slight electric field applied between a substrate and the floating gate, which causes an inversion of the memory cell state from an erased state “1” to a programmed state “0”. That is to say, data may be destroyed due to repetitive weak programming during the read operations, which is referred to as the “read retention error”.

In a first aspect of the present invention, a semiconductor memory device is provided. The semiconductor memory device has: a first memory including a data storage area and a redundant data storage area; a second memory as a nonvolatile memory storing a defect address of the first memory; a register configured to store the defect address; a sequencer; and a decoder. The sequencer reads out the defect address from the second memory and stores the read defect address in the register. When accessing a target address in the first memory, the decoder compares the target address with the defect address stored in the register, and selects any of the data storage area and the redundant data storage area of the first memory based on a result of the above-mentioned comparison.

As described above, the sequencer reads out the defect address from the second memory and stores the read defect address in the register before the first address is accessed. When the first memory is accessed, the decoder does not refer to the target address stored in the second memory but refers to the target address stored in the register. Therefore, the number of access times to the second memory is reduced. It is thus possible to suppress the read retention error in the second memory and to hold the defect address well in the second memory, which improves reliability of the semiconductor memory device.

In a second aspect of the present invention, a method of operating a semiconductor memory device is provided. The semiconductor memory device has: a first memory including a data storage area and a redundant data storage area; a second memory as a nonvolatile memory storing a defect address of the first memory; and a register. The method includes: (A) reading out the defect address from the second memory and storing the read defect address in the register; (B) when accessing a target address in the first memory, comparing the target address with the defect address stored in the register; and (C) selecting any of the data storage area and the redundant data storage area of the first memory based on a result of the comparison in the (B) step.

In a third aspect of the present invention, a semiconductor memory device is provided. The semiconductor memory device has a first nonvolatile memory, a second nonvolatile memory, a register group, and a sequencer. The first nonvolatile memory has a plurality of data storage areas and at least one redundant data storage area. The second nonvolatile memory stores replacement addresses (defect addresses) out of a plurality of addresses corresponding to respective of the plurality of data storage areas in the first nonvolatile memory. The sequencer reads out all the replacement addresses from the second nonvolatile memory, and stores the all replacement addresses in the register group in response to an operation command. The all replacement addresses are related to respective addresses of the at least one redundant data storage area. The first nonvolatile memory is accessed based on a result of comparison between a target address in the first nonvolatile memory and the all replacement addresses stored in the register group.

According to the semiconductor memory device of the present invention, the number of access times to the second memory is reduced. It is thus possible to suppress the read retention error in the second memory holding the defect addresses (replacement addresses).

### BRIEF DESCRIPTION OF THE DRAWINGS

The above and other objects, advantages and features of the present invention will be more apparent from the following description taken in conjunction with the accompanying drawings, in which:

FIG. 1 is a block diagram showing a configuration of a conventional semiconductor memory device;

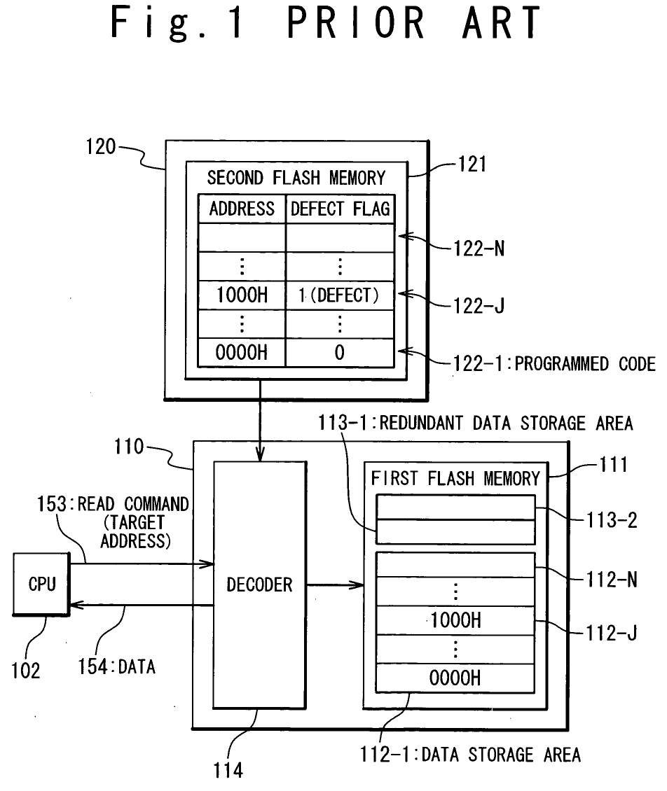

FIG. 2 is a block diagram showing a configuration of a semiconductor memory device according to the present invention;

FIG. 3 is a timing chart showing a terminal reset signal 51 and an internal reset signal 52 in the semiconductor memory device according to the present invention;

FIG. 4 is a block diagram showing a configuration of a flash macro 4-i (i is an integer not less than 1 and not more than 4) in the semiconductor memory device according to the present invention;

FIG. 5 is a flowchart showing an initial setting as an operation of the semiconductor memory device according to the present invention;

FIG. 6 is a flowchart showing command execution and replacement control as operations of the semiconductor memory device according to the present invention;

FIG. 7 is a block diagram for explaining an operation of the semiconductor memory device according to the present invention;

FIG. 8 is a block diagram for explaining another operation of the semiconductor memory device according to the present invention;

FIG. 9 is a block diagram for explaining still another operation of the semiconductor memory device according to the present invention; and

FIG. 10 is a block diagram for explaining still another operation of the semiconductor memory device according to the present invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

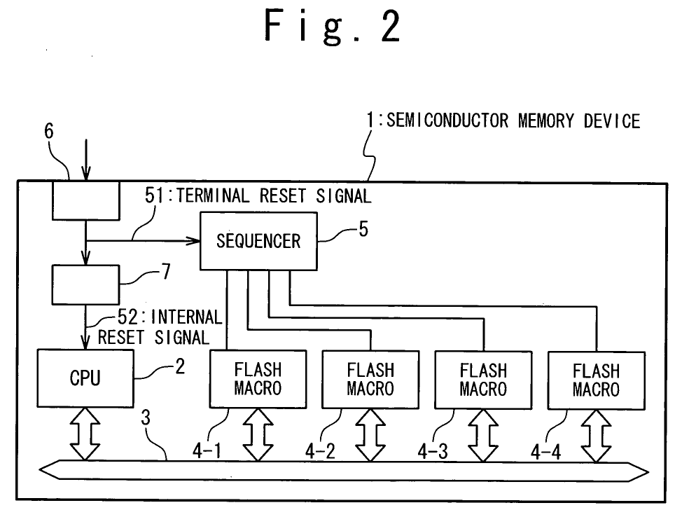

FIG. 2 is a block diagram showing a configuration of a semiconductor memory device 1 according to the present invention. The semiconductor memory device 1 according to the present invention has a CPU 2, flash macros 4-1 to 4-4, a sequencer 5, a reset controller 6 and an internal reset controller 7. The CPU 2, the flash macros 4-1 to 4-4, the sequencer 5 and the internal reset controller 7 operate in accordance with a clock signal (not shown).

The reset controller 6 outputs a terminal reset signal 51 as an operation command to the sequencer 5 when a power supply is turned on. The reset controller 6 is exemplified by a switch that is operated by a user.

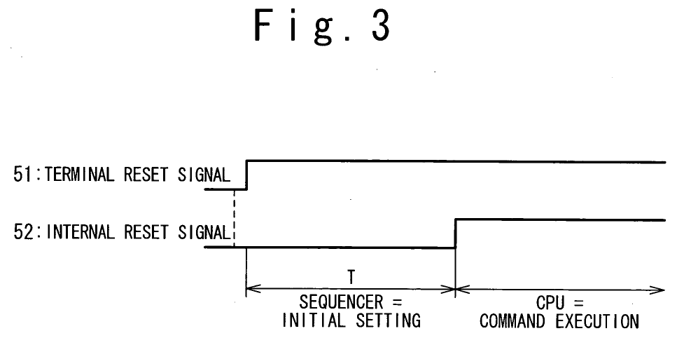

The internal reset controller 7 receives the terminal reset signal 51. As shown in FIG. 3, a predetermined time T after receiving the terminal reset signal 51, the internal reset controller 7 outputs an internal reset signal 52 to the CPU 2. Here, the predetermined time T can be scaled based on the number of clock signals supplied to the internal reset controller 7.

The sequencer 5 accesses the flash macros 4-1 to 4-4 in response to the terminal reset signal 51, and performs (processes) initial settings to be described later. As shown in FIG. 3, the initial settings are performed during the predetermined time T. In the predetermined time T, the sequencer 5 may access the flash macros 4-1 to 4-4 in order with changing address, or may access them simultaneously. In an example described below, a case where the sequencer 5 accesses the flash macro 4-1 will be explained.

The CPU 2 receives the internal reset signal 52. When receiving the internal reset signal 52, the CPU 2 performs (processes) command execution to be described later. As shown in FIG. 3, the command execution is performed after the initial settings are completed. In the command execution, the CPU 2 outputs a read command including a target address (input address) to the flash macro 4-1 through a bus 3. In response to the read command, the flash macro 4-1 outputs data to the CPU 2 through the bus 3.

As described above, the initial settings are carried out before the CPU 2 performs the command execution. In other words, the sequencer 5 operates before the read command is output to access the target address. It is preferable that the sequencer 5 carries out the initial settings when the semiconductor memory device 1 is powered on.

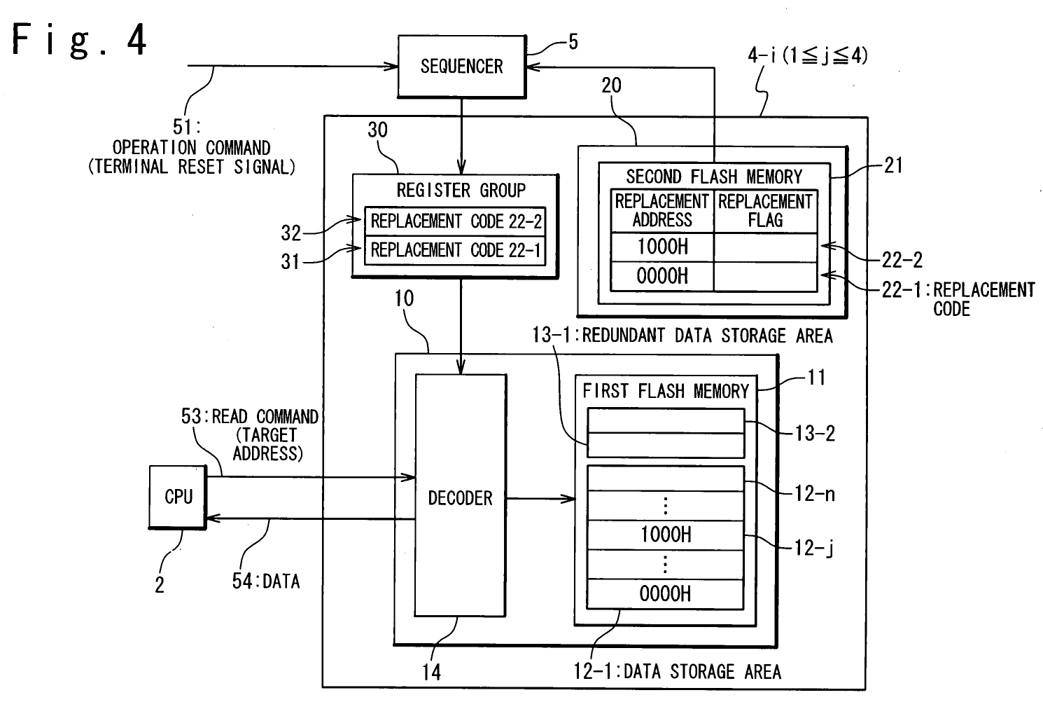

FIG. 4 is a block diagram showing a configuration of a flash macro 4-i (i is an integer not less than 1 and not more than 4) in the semiconductor memory device 1 according to the present invention. The flash macro 4-i includes a first flash memory unit 10, a second flash memory unit 20 and a register group 30.

The first flash memory unit 10 has a first flash memory 11 as a nonvolatile memory and a decoder 14. The first flash memory 11 includes a plurality of data storage areas (e.g. memory cells or sectors) and at least one redundant data storage area (e.g. redundant memory cell or redundant sector). In FIG. 4, for example, the first flash memory 11 includes a plurality of data storage areas 12-1 to 12-n (n is an integer equal to or more than 1), and two redundant data storage areas 13-1 and 13-2.

The second flash memory unit 20 includes a second flash memory 21 as a nonvolatile memory. The second flash memory 21 stores therein replacement codes 22-1 and 22-2. Each of the replacement codes 22-1 and 22-2 is information regarding the replacement of a data storage area by a redundant storage area in the first flash memory 11. More specifically, the plurality of replacement codes 22-1 and 22-2 includes a plurality of replacement addresses (defect addresses) and a plurality of replacement flags, respectively. The replacement address (defect address) is an address of a defect data storage area to be replaced by a redundant storage area. In FIG. 4, for example, replacement addresses in the replacement codes 22-1 and 22-2 are “0000H” and “1000H”, respectively. The plurality of replacement addresses “0000H” and “100H” correspond to addresses of a plurality of data storage areas 12-1 and 12-j (j is an integer not less than 1 and not more than n) in the first flash memory 11, respectively. Further, the replacement addresses “0000H” and “1000H” are related to addresses of the redundant data storage areas 13-1 and 13-2, respectively. Each of the plurality of replacement flags indicates “0” or “1”. In a case where the replacement flag included in the replacement code 22-2 indicates “0”, the address “1000H” included in the replacement code 22-2 corresponds to the address of the redundant data storage area 13-2.

The register group 30 includes registers 31 and 32. Each of the register 31 or 32 is configured to store a replacement code 22 including a replacement address (defect address). In response to the terminal reset signal 51, the sequencer 5 reads out all of the replacement codes 22-1 and 22-2 from the second flash memory 21 in the flash macro 4-1, and then stores the read replacement codes 22-1 and 22-2 in the register group 30 in the flash macro 4-1. Here, the read replacement codes 22-1 and 22-2 are stored in this order in the registers 31 and 32, respectively.

According to the present embodiment, whether the semiconductor memory device 1 is shipped or not is determined on the basis of the number of defects in the data storage areas of the first flash memory 11. With regard to the defects, the following three cases (A), (B) and (C) can be considered.

In the case (A), the number of defects in the data storage areas in the first flash memory 11 is equal to or more than three. For example, the data storage areas 12-1, 12-2 and 12-j have deficiencies. In this case, the number of defect data storage areas excesses replacement ability. In other words, it is not possible to distribute the redundant data storage areas 13-1 and 13-2 to all the defect data storage areas 12-1, 12-2 and 12-j. Therefore, the semiconductor memory device 1 is not shipped in the case (A).

In the case (B), the number of defects in the data storage areas in the first flash memory 11 is one. For example, only the data storage area 12-j has a deficiency. In this case, an address “0000H” corresponding to the data storage area 12-1 is arbitrarily selected as a dummy replacement address, and a replacement code 22-1 including the dummy replacement address “0000H” and a replacement flag “1” is programmed in the second flash memory 21 before the shipment. In addition, a replacement code 22-2 including a replacement address “1000H” corresponding to the defect data storage area 12-j and a replacement flag “0” is programmed in the second flash memory 21 before the shipment. In this manner, the redundant data storage area 13-2 is allocated to the defect data storage area 12-j, and thus the semiconductor memory device 1 can be shipped. The redundant data storage area 13-1 allocated to the data storage area 12-1 is regarded as dummy information.

In the case (C), the number of defects in the data storage areas in the first flash memory 11 is two. For example, the data storage areas 12-1 and 12-j have deficiencies. In this case, a replacement code 22-1 including a replacement address “0000H” corresponding to the defect data storage area 12-1 and a replacement flag “0” is programmed in the second flash memory 21 before the shipment. In addition, a replacement code 22-2 including a replacement address “1000H” corresponding to the defect data storage area 12-j and a replacement flag “0” is programmed in the second flash memory 21. In this manner, the redundant data storage areas 13-1 and 13-2 are allocated to the defect data storage areas 12-1 and 12-j, respectively. Therefore, the semiconductor memory device 1 can be shipped.

Next, operations of the semiconductor memory device 1 according to the present embodiment will be described below in detail.

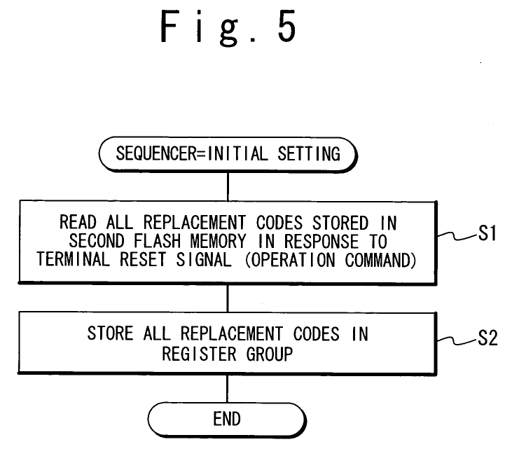

The sequencer 5 performs (processes) an “initial setting” as one of its operations. The initial setting will be explained below in reference to FIG. 5.

The sequencer 5 accesses the flash macro 4-1 in response to the terminal reset signal 51 (operation command). At this time, the sequencer 5 reads all the replacement codes 22-1 and 22-2 stored in the second flash memory 21 of the flash macro 4-1 (Step S1). Then, the sequencer 5 stores all of the read replacement codes 22-1 and 22-2 in respective of the registers 31 and 32 in the register group 30 of the flash macro 4-1 (Step S2). As shown in FIG. 3, the initial setting is carried out before the CPU 2 performs the command execution. It is preferable that the sequencer 5 carries out the initial setting when the semiconductor memory device 1 is powered on.

The CPU 2 performs (processes) command execution as one of its operations when receiving the internal reset signal 52. In the command execution, the CPU 2 outputs a read command 53 including a target address to the flash macro 4-1. In response to the read command 53, the decoder 14 of the first flash memory unit 10 in the flash macro 4-1 performs (processes) a replacement control as one of its operations. In the replacement control, the decoder 14 in the flash macro 4-1 accesses the first flash memory 11 in the flash macro 4-1 in response to the read command 53, reads out data from the target address in the first flash memory 11, and then outputs the read data back to the CPU 2

Examples of the command execution and the replacement control in the above-mentioned case (B) will be described below.

Case (B-1):

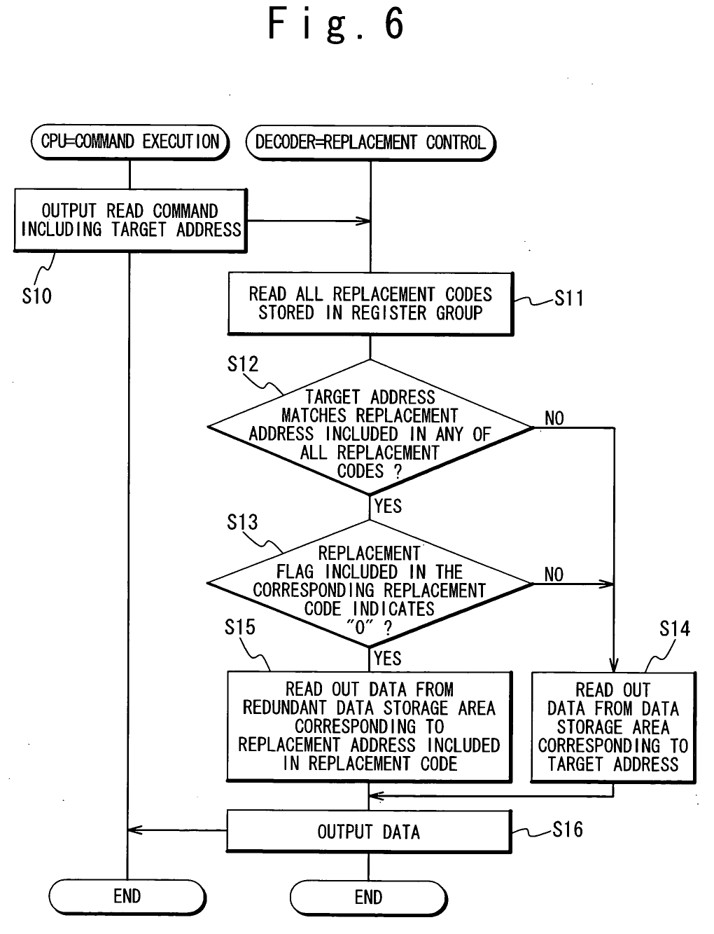

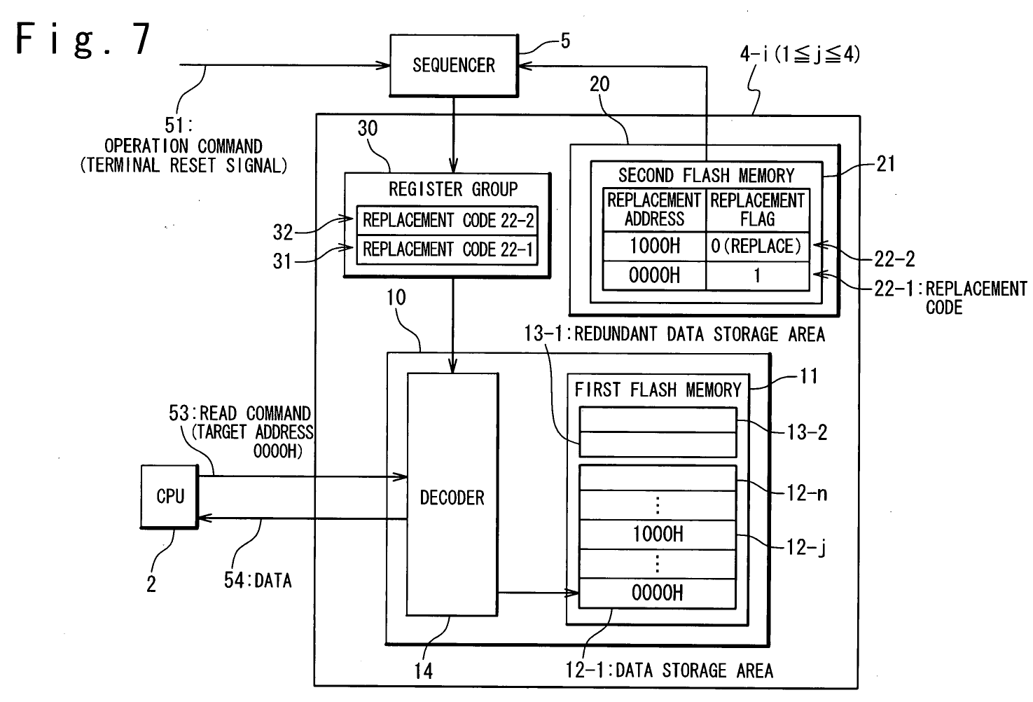

Referring to FIGS. 6 and 7, a case (B-1) will be first explained. In the case (B-1), the CPU 2 outputs a read command 53 including a target address “0000H”, and the replacement flag included in the replacement code 22-1 corresponding to the target address “0000H” indicates “1” as shown in FIG. 7.

First, the CPU 2 outputs the read command 53 including the target address “0000H” to the decoder 14 in the flash macro 4-1 (Step S10).

In the flash macro 4-1, the decoder 14 reads all the replacement codes 22-1 and 22-2 from the register group 30 in response to the read command 53 (Step S11).

The decoder 14 compares the target address “0000H” included in the read command 53 with the replacement addresses (defect addresses) included in the replacement codes 22-1 and 22-2 (Step S12).

Here, a result of the comparison between the addresses indicates that the target address “0000H” included in the read command 53 matches the dummy address “0000H” included in the replacement code 22-1 (Step S12; Yes). In this case, the decoder 14 checks whether or not the replacement flag included in the replacement code 22-1 indicates “0” (Step S13).

As a result of the check of the replacement flag, the replacement flag included in the replacement code 22-1 indicates “1 (dummy)” (Step S13; No). In this case, the decoder 14 reads out data from the data storage area 12-1 corresponding to the target address “0000H” out of the plurality of data storage areas 12-1 to 12-n in the first flash memory 11 (Step S14).

The decoder 14 outputs the read data as data 54 to the CPU 2 (Step S16).

If a result of the comparison between the addresses indicates that the target address included in the read command 53 does not match any of the replacement addresses (defect addresses) included in the replacement codes 22-1 and 22-2 (Step S12; No), the decoder 14 executes the above-mentioned Step S14 and S16. That is to say, when the target address is different from the defect addresses, the decoder 14 accesses the data storage area corresponding to the target address in the first flash memory 11.

Case (B-2):

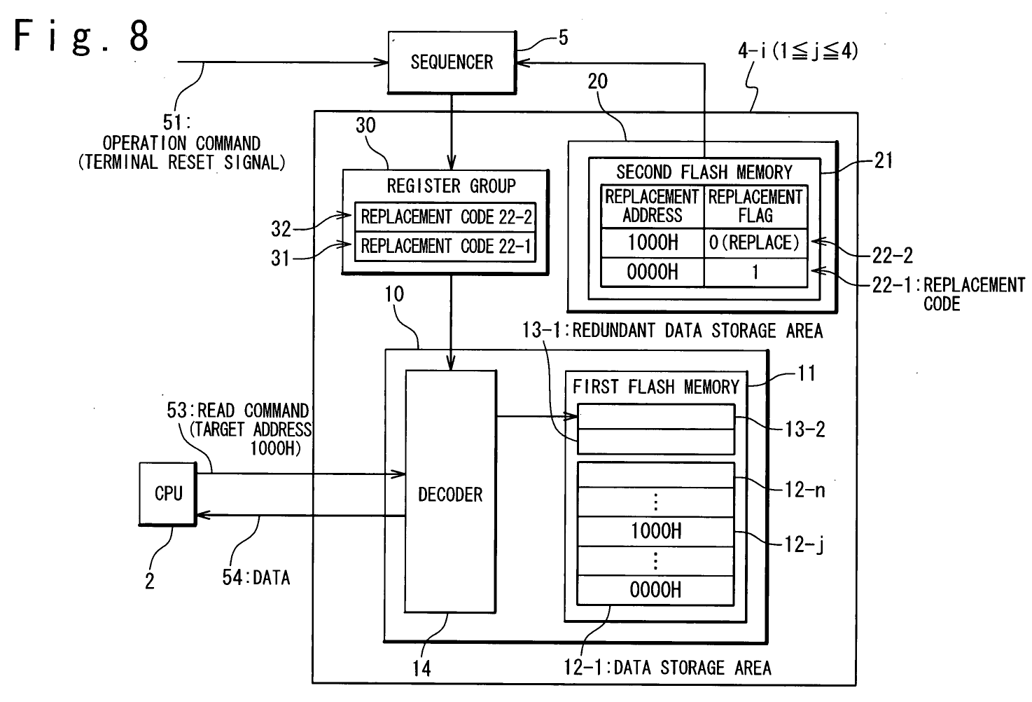

Next, with reference to FIGS. 6 and 8, a case (B-2) will be explained. In the case (B-2), the CPU 2 outputs a read command 53 including a target address “1000H”, and the replacement flag included in the replacement code 22-2 corresponding to the target address “1000H” indicates “0” as shown in FIG. 8.

First, the CPU 2 outputs the read command 53 including the target address “1000H” to the decoder 14 in the flash macro 4-1 (Step S10).

In the flash macro 4-1, the decoder 14 reads all the replacement codes 22-1 and 22-2 from the register group 30 in response to the read command 53 (Step S11).

The decoder 14 compares the target address “1000H” included in the read command 53 with the replacement addresses (defect addresses) included in the replacement codes 22-1 and 22-2 (Step S12).

Here, a result of the comparison between the addresses indicates that the target address “1000H” included in the read command 53 matches the replacement address (defect address) “100H” included in the replacement code 22-2 (Step S12; Yes). In this case, the decoder 14 checks whether or not the replacement flag included in the replacement code 22-2 indicates “0” (Step S13).

As a result of the check of the replacement flag, the replacement flag included in the replacement code 22-2 indicates “0” (Step S13; Yes). In this case, the decoder 14 reads out data from the redundant data storage area 13-2 corresponding to the replacement address “1000H” included in the replacement code 22-2 out of the redundant data storage areas 13-1 and 13-2 in the first flash memory 11 (Step S15).

The decoder 14 outputs the read data as data 54 to the CPU 2 (Step S16).

In the case (B), as described above, the sequencer 5 carries out the initial setting when the power supply is turned on. More specifically, when the power supply is turned on, the sequencer 5 reads all of the replacement codes 22-1 and 22-2 stored in the second flash memory 21 of the flash macro 4-1, and stores them in the register group 30 of the flash macro 4-1. As the command execution, the CPU 2 outputs the read command 53 including the target address to the decoder 14 in the flash macro 4-1. Then, the decoder 14 carries out the replacement control. When accessing the target address in the first flash memory 11, the decoder 14 compares the target address with all the replacement addresses stored in the register group 30, and selects any of the data storage area and the redundant storage area in the first flash memory 11 based on a result of the comparison. In other words, the decoder 14 accesses the data storage area or redundant data storage area in the first flash memory 11 based on the result of the comparison.

According to the semiconductor memory device 1 of the present invention, the replacement codes 22-1 and 22-2 (the replacement addresses and the replacement flags) are read from the second flash memory 21 only when the power supply is turned on. In the command execution and the replacement control, the replacement codes 22-1 and 22-2 are read out not from the second flash memory 21 but from the register group 30. As a consequence, the number of access times to the second flash memory 21 is reduced in the semiconductor memory device 1 according to the present invention. It is thus possible to suppress the read retention error in the second memory 21 in which the replacement addresses (defect addresses) are stored. The reliability of the semiconductor memory device 1 according to the present invention is thus improved.

Moreover, according to the present invention, the semiconductor memory device 1 in the case (B) can be shipped, since the read retention error is suppressed.

Next, examples of the command execution and the replacement control in the above-mentioned case (C) will be described below.

Case (C-1):

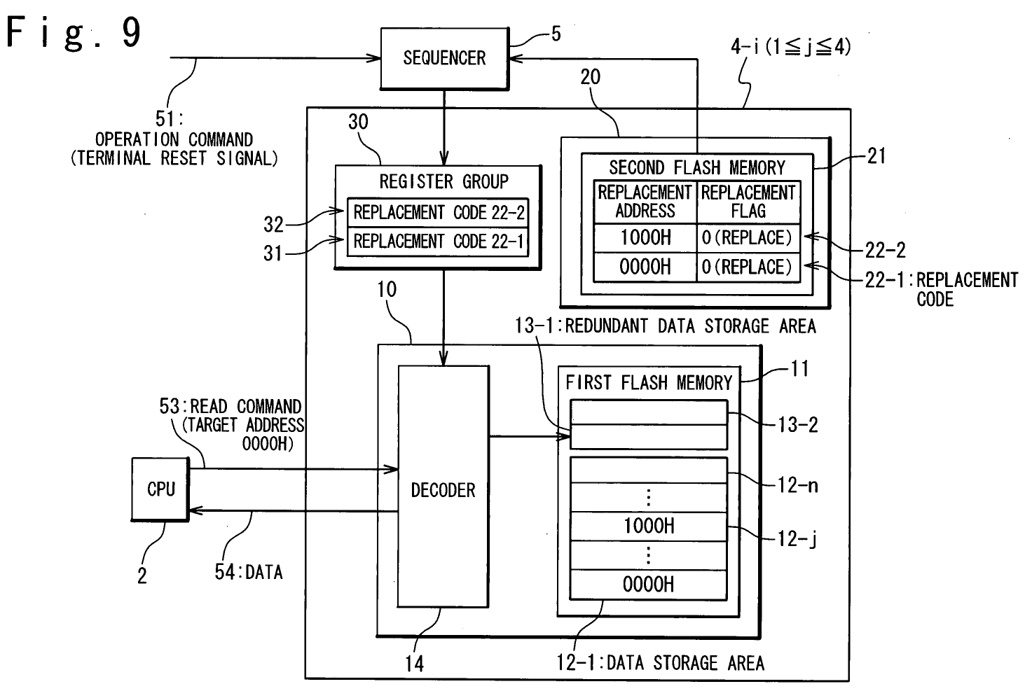

Referring to FIGS. 6 and 9, a case (C-1) will be first explained. In the case (C-1), the CPU 2 outputs a read command 53 including a target address “0000H”, and the replacement flag included in the replacement code 22-1 corresponding to the target address “0000H” indicates “0” as shown in FIG. 9.

First, the CPU 2 outputs the read command 53 including the target address “0000H” to the decoder 14 in the flash macro 4-1 (Step S10).

In the flash macro 4-1, the decoder 14 reads all the replacement codes 22-1 and 22-2 from the register group 30 in response to the read command 53 (Step S11).

The decoder 14 compares the target address “0000H” included in the read command 53 with the replacement addresses (defect addresses) included in the replacement codes 22-1 and 22-2 (Step S12).

Here, a result of the comparison between the addresses indicates that the target address “0000H” included in the read command 53 matches the replacement address “0000H” included in the replacement code 22-1 (Step S12; Yes). In this case, the decoder 14 checks whether or not the replacement flag included in the replacement code 22-1 indicates “0” (Step S13).

As a result of the check of the replacement flag, the replacement flag included in the replacement code 22-1 indicates “0” (Step S13; Yes). In this case, the decoder 14 reads out data from the redundant data storage area 13-1 corresponding to the replacement address “0000H” included in the replacement code 22-1 out of the redundant data storage areas 13-1 and 13-2 in the first flash memory 11 (Step S15).

The decoder 14 outputs the read data as data 54 to the CPU 2 (Step S16).

Case (C-2):

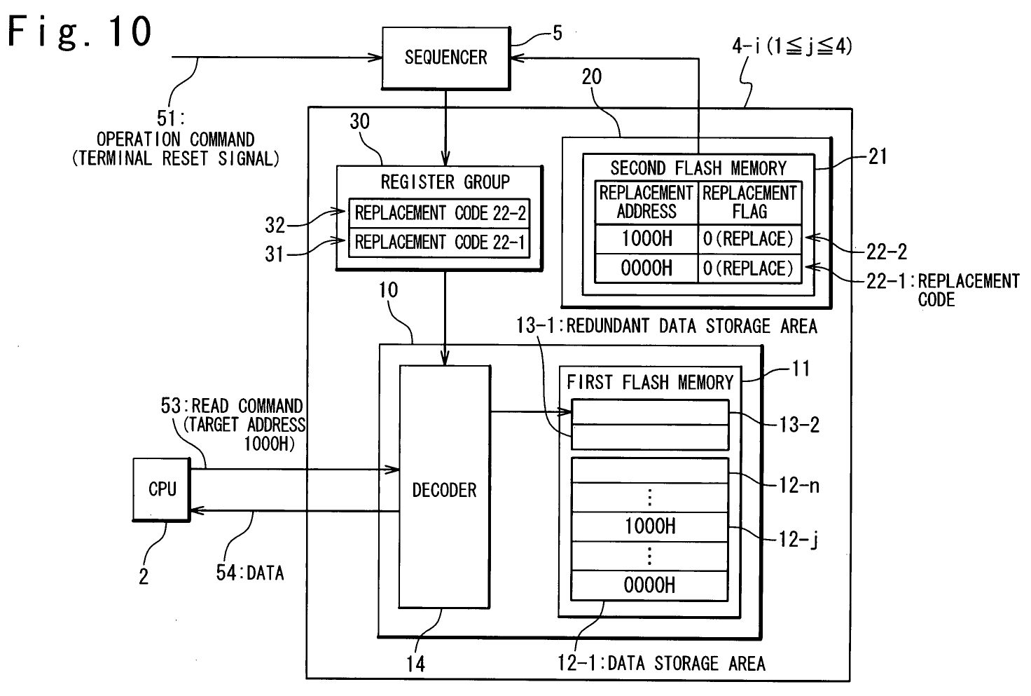

Next, with reference to FIGS. 6 and 10, a case (C-2) will be explained. In the case (C-2), the CPU 2 outputs a read command 53 including a target address “1000H”, and the replacement flag included in the replacement code 22-2 corresponding to the target address “1000H” indicates “0” as shown in FIG. 10. The reading operation in the command execution in the case (C-2) is the same as in the case (B-2).

First, the CPU 2 outputs the read command 53 including the target address “1000H” to the decoder 14 in the flash macro 4-1 (Step S10).

In the flash macro 4-1, the decoder 14 reads all the replacement codes 22-1 and 22-2 from the register group 30 in response to the read command 53 (Step S11).

The decoder 14 compares the target address “1000H” included in the read command 53 with the replacement addresses (defect addresses) included in the replacement codes 22-1 and 22-2 (Step S12).

Here, a result of the comparison between the addresses indicates that the target address “1000H” included in the read command 53 matches the replacement address (defect address) “1000H” included in the replacement code 22-2 (Step S12; Yes). In this case, the decoder 14 checks whether or not the replacement flag included in the replacement code 22-2 indicates “0” (Step S13).

As a result of the check of the replacement flag, the replacement flag included in the replacement code 22-2 indicates “0” (Step S13; Yes). In this case, the decoder 14 reads out data from the redundant data storage area 13-2 corresponding to the replacement address “1000H” included in the replacement code 22-2 out of the redundant data storage areas 13-1 and 13-2 in the first flash memory 11 (Step S15).

The decoder 14 outputs the read data as data 54 to the CPU 2 (Step S16).

According to the semiconductor memory device 1 of the present invention, the replacement codes 22-1 and 22-2 (the replacement addresses and the replacement flags) are read from the second flash memory 21 only when the power supply is turned on. In the command execution and the replacement control, the replacement codes 22-1 and 22-2 are read out not from the second flash memory 21 but from the register group 30. As a consequence, the number of access times to the second flash memory 21 is reduced in the semiconductor memory device 1 according to the present invention. It is thus possible to suppress the read retention error in the second memory 21 in which the replacement addresses (defect addresses) are stored. The reliability of the semiconductor memory device 1 according to the present invention is thus improved.

Moreover, according to the present invention, the semiconductor memory device 1 in the case (C) can be shipped, since the read retention error is suppressed.

In the above embodiment, a case where the first flash memory 11 is a nonvolatile flash memory is described. However, the first flash memory 11 is not limited to the above embodiment. Any memory having redundant memory cells can be applied instead of the first flash memory 11. Moreover, the second flash memory 21 is not limited to the above embodiment. Any nonvolatile memory in which the read retention error may occur can be applied instead of the second flash memory 21.

It is apparent that the present invention is not limited to the above embodiment, and that may be modified and changed without departing from the scope and spirit of the invention.

What is claimed is:

1. A semiconductor memory device comprising:
a first memory including a data storage area and a redundant data storage area;
a second memory as a nonvolatile memory storing a defect address of said first memory;
a register configured to store said defect address;
a sequencer configured to read out said defect address from said second memory and store said read defect address in said register; and
a decoder configured to, when accessing a target address in said first memory, compare said target address with said defect address stored in said register and select any of said data storage area and said redundant data storage area of said first memory based on a result of said comparison.

2. The semiconductor memory device according to claim 1,
wherein said sequencer operates before said decoder accesses said target address.

3. The semiconductor memory device according to claim 1,
wherein said sequencer operates when the semiconductor memory device is powered on.

4. The semiconductor memory device according to claim 1,
wherein when said target address is different from said defect address, said decoder accesses said data storage area corresponding to said target address in said first memory.

5. The semiconductor memory device according to claim 4,
wherein when said target address matches said defect address, said decoder accesses said redundant data storage area corresponding to said defect address.

6. The semiconductor memory device according to claim 3,
wherein when said target address is different from said defect address, said decoder accesses said data storage area corresponding to said target address in said first memory.

7. The semiconductor memory device according to claim 6,
wherein when said target address matches said defect address, said decoder accesses said redundant data storage area corresponding to said defect address.

8. A method of operating a semiconductor memory device,
said semiconductor memory device having: a first memory including a data storage area and a redundant data storage area; a second memory as a nonvolatile memory storing a defect address of said first memory; and a register,
said method comprising:
(A) reading out said defect address from said second memory and storing said read defect address in said register;
(B) when accessing a target address in said first memory, comparing said target address with said defect address stored in said register; and
(C) selecting any of said data storage area and said redundant data storage area of said first memory based on a result of said comparison in said (B) step.

9. The method according to claim 8,
wherein said (A) step is carried out before said target address is accessed.

10. The method according to claim 8,
wherein said (A) step is carried out when said semiconductor memory device is powered on.

11. The method according to claim 8,
wherein when said target address is different from said defect address in said (B) step, said data storage area corresponding to said target address in said first memory is selected in said (C) step.

12. The method according to claim 11,
wherein when said target address matches said defect address in said (B) step, said redundant data storage area corresponding to said defect address is selected in said (C) step.

13. The method according to claim 10,
wherein when said target address is different from said defect address in said (B) step, said data storage area corresponding to said target address in said first memory is selected in said (C) step.

14. The method according to claim 13,
wherein when said target address matches said defect address in said (B) step, said redundant data storage area corresponding to said defect address is selected in said (C) step.

15. A semiconductor memory device comprising:
a first nonvolatile memory having a plurality of data storage areas and at least one redundant data storage area;
a second nonvolatile memory storing replacement addresses out of a plurality of addresses corresponding to respective of said plurality of data storage areas in said first nonvolatile memory;
a register group; and
a sequencer configured to read out all said replacement addresses from said second nonvolatile memory and store said all replacement addresses in said register group in response to an operation command,
wherein said all replacement addresses are related to respective addresses of said at least one redundant data storage area, and
said first nonvolatile memory is accessed based on a result of comparison between a target address in said first nonvolatile memory and said all replacement addresses stored in said register group.

16. The semiconductor memory device according to claim 15, further comprising a decoder configured to read said all replacement addresses stored in said register group in response to a read command including said target address and access said first nonvolatile memory,
wherein when said target address does not match said all replacement addresses read from said register group, said decoder reads out data from one of said plurality of data storage areas that corresponds to said target address, and
when said target address matches any one of said all replacement addresses read from said register group, said decoder reads out data from one of said at least one redundant data storage area that corresponds to said any one replacement address.

17. The semiconductor memory device according to claim 16, further comprising a CPU configure to output said read command,
wherein said decoder accesses said first nonvolatile memory in response to said read command, and outputs to said CPU said data read out from said first nonvolatile memory.

18. The semiconductor memory device according to claim 15, further comprising a reset controller configured to output said operation command to said sequencer when the semiconductor memory device is powered on.

19. The semiconductor memory device according to claim 16, further comprising a reset controller configured to output said operation command to said sequencer when the semiconductor memory device is powered on.

20. The semiconductor memory device according to claim 17, further comprising a reset controller configured to output said operation command to said sequencer when the semiconductor memory device is powered on.
